(19) United States
(12) Patent Application Publication
(10) Pub. No.: US 2014/0291494 A1
(43) Pub. Date: Oct. 2, 2014

(54) OPTICAL COMMUNICATION MODULE

(71) Applicants: AUTONETWORKS TECHNOLOGIES, LTD., Yokohama-shi, Kanagawa (JP); SUMITOMO WIRING SYSTEMS, LTD., Yokkaichi, Mie (JP); SUMITOMO ELECTRIC INDUSTRIES, LTD., Osaka-shi, Osaka (JP)

(72) Inventor: Shigeo Hayashi, Yokkaichi (JP)

(21) Appl. No.: 14/355,749

(22) PCT Filed: Dec. 1, 2012
(86) PCT No.: PCT/JP2012/078293

§ 371 Date: May 1, 2014

(30) Foreign Application Priority Data
Dec. 2, 2011 (JP) 2011-241622

(51) Int. Cl. H04B 10/50; H01S 5/022; G01J 1/04

(52) U.S. Cl. CPC H04B 10/501; G01J 1/0411; H01S 5/02288
USPC 250/216; 372/43.01

(57) ABSTRACT

An optical communication module has a conversion element, a bendable conductive plate, a first resin cast body, a second resin cast body, and a lens part. The conversion element converts an optical signal to an electrical signal or an electrical signal to an optical signal. The conductive plate has the conversion element mounted thereto. The first resin cast body is cast with a first portion of the conductive plate embedded therein. The second resin cast body is cast with a second portion of the conductive plate embedded therein. The lens part is provided on the second resin cast body. The conversion element is mounted to the first portion of the conductive plate. The first resin cast body and the second resin cast body are fixed with the conductive plate bent such that the conversion element faces the lens part.

### BACKGROUND

This application claims priority to JP 2011-241622 filed in Japan on Nov. 2, 2011, the entire disclosure of which is hereby incorporated by reference in its entirety.

The present invention relates to an optical communication module which packages a conversion element such as a laser diode and/or a photodiode for carrying out optical communication.

Conventionally, optical communication using optical fibers and the like has become widely used. Optical communication is carried out by converting an electrical signal to an optical signal using a conversion element such as a laser diode, transmitting and receiving the optical signal via an optical fiber, and converting the received optical signal to an electrical signal with a conversion element such as a photodiode. Accordingly, an optical communication module has been widely used in which, in some instances, a conversion element such as a laser diode and/or a photodiode is formed together in a single package with a peripheral circuit element for driving the conversion element. This optical communication module is called an OSA (Optical Sub-Assembly). In recent years, various inventions have been made relating to optical communication devices and optical communication modules.

For example, in Japanese Unexamined Patent Application Publication No. 2005-167189, a photoelectric conversion module has been proposed comprising a photoelectric element which transmits or receives an optical signal, a stem for fixing the photoelectric element, a cap for covering the photoelectric element, and a plurality of leads which apply electrical signals to the photoelectric element or convey electrical signals from the photoelectric element. A planar section is provided at one end of a prescribed lead positioned within a package formed from the stem and the cap. An electrical circuit component is provided at this planar section, one end of the electrical circuit being connected to the photoelectric element and another end being connected to the lead. With such a structure, the high frequency characteristic is excellent and the photoelectric conversion module can be reduced in size.

### SUMMARY

The inventors of this application invented the following optical communication module structure and have already filed an application (this optical communication module will be called an existing optical communication module). FIG. 7 is a schematic cross-sectional view showing the structure of the existing optical communication module. In the drawing, 101 is the existing optical communication module, and has a structure in which a photoelectric conversion element 105 and a conductive plate 103 to which the photoelectric conversion element 105 is connected are housed in a translucent housing body 102. The housing body 102 is a resin cast member formed of translucent material such as a synthetic resin (translucent resin). A bottom part 21 having a plan view, for example, substantially forming a square, a peripheral wall 22 provided on an upper surface of the bottom part 21, a cylindrical part 123 protruding from a lower surface of the bottom part 21, and a lens part 124 provided substantially at the center of the lower surface of the bottom part 21 are formed as a one-piece member. In the housing body 102, a recess 25 housing the photoelectric conversion element 105 is formed by the bottom part 21 and the peripheral wall 22.

In the housing body 102 of the optical communication module 101, at an upper surface of the bottom part 21 (the bottom surface of the recess 25), a plurality of conductive plates 103 is embedded with the upper surfaces exposed at the inside of the recess 25, the photoelectric conversion element 105 being mounted above one conductive plate 103. An opening 131 is formed in the conductive plate 103 at a position facing the lens part 124 provided at the lower surface of the bottom part 21, and the photoelectric conversion element 105 is disposed above the opening 131 of the conductive plate 103.

The photoelectric conversion element 105 has a rectangular main body part 151 having a plan view substantially forming a square, a photo-receiving part or a photo-emitting part (omitted from the drawings) provided substantially at the center of the lower surface of the main body part 151, first terminals 152 provided at the periphery of the photo-receiving part or the photo-emitting part at the lower surface of the main body part 151, and a second terminal 153 provided at the upper surface of the main body part 151. The first terminals 152 and the second terminal 153 are for communicating electrical signals between the photoelectric conversion element 105 and the conductive plate 103, and are, for example, the anode terminal and the cathode terminal of a photodiode or a laser diode. With the photoelectric conversion element 105, the first terminals 152 are connected to the conductive plate 103 by way of soldering, and the second terminal 153 is connected via a wire 35 (wire bonding). In addition, at the upper end part of the peripheral wall 22 of the housing body 102, a cover body 126 having a substantially square plate form is fixed, and the recess 25 is sealed.

The existing optical communication module 101 having this kind of structure is able to achieve a price reduction based on a reduction in the number of components, an ease of manufacturing, and the like. Yet, this existing optical communication module 101 requires the use of a structural member providing a photo-receiving part or a photo-emitting part at the lower surface (the surface at which is provided the terminal connecting with the conductive plate 103) of the main body 151 as the photoelectric conversion element 105. However, there are also photoelectric conversion elements that have a structure in which a photo-receiving part or a photo-emitting part is provided at the upper surface of the photoelectric conversion element, and the existing optical communication module 101 was not able to use this kind of photoelectric conversion element.

Preferred embodiments were made in view of such circumstances and have as an object the provision of an optical communication module equipped with a photoelectric conversion element provided with a photo-receiving part or a photo-emitting part at an upper surface (a surface opposite from the surface on which is provided the terminal connecting with the conductive plate) of the main body part, and able to achieve a price reduction, ease of manufacturing, and the like based on a reduction in the number of components.

An optical communication module according to a preferred embodiment is an optical communication module having a conversion element for converting an optical signal to an electrical signal or an electrical signal to an optical signal, and comprises a bendable conductive plate on which the conversion element is mounted, a first body possibly resin cast with a portion of the conductive plate embedded therein, a second body separated from the first resin cast body by a prescribed distance and made, for example, by a resin cast with another portion of the conductive plate embedded therein, and a lens part provided on the second resin cast body, the conversion element being mounted on the portion of the conductive plate embedded in the first resin cast body, the first resin cast body and the second resin cast body being fixed with the conductive plate bent such that the conversion element faces the lens part.

In addition, an optical communication module according to a preferred embodiment is characterized in that the second resin cast body can be cast from translucent synthetic resin, and the lens part can be cast as a one-piece member with the second resin cast body.

In addition, an optical communication module according to a preferred embodiment may be characterized in that the first resin cast body may have a bottom part and a peripheral wall surrounding the bottom part, the portion of the conductive plate may be embedded in the first resin cast body such that a part or a whole of a surface is exposed at the bottom part, and the second resin cast body may be fixed extending to an entire periphery of an end part of the peripheral wall.

In addition, an optical communication module according to a preferred embodiment may be characterized in that the first resin cast body can be cast from translucent synthetic resin, and the conversion element may be embedded in the first resin cast body.

In addition, an optical communication module according to a preferred embodiment may be characterized in that a cylindrical part is provided cast as a one-piece member with the second resin cast body and in which an optical communication line may be fitted, and the conversion element may be arranged to communicate optical signals, through the lens part, with the optical communication line that is fitted in the cylindrical part.

In a preferred embodiment, the first resin cast body with the portion of the bendable conductive plate embedded therein may be provided together with the second resin cast body separated by a prescribed distance and having another portion of the conductive plate embedded therein. The conversion element for converting an electrical signal and an optical signal may be mounted to the portion of the conductive plate embedded in the first resin cast body. In addition, the lens part may be provided to the second resin cast body.

Because of this, the first resin cast body and the second resin cast body are situated connected via the conductive plate, and therefore the first resin cast body and the second resin cast body are fixed with the conductive plate bent. In this case, the first resin cast body and the second resin cast body may be positioned such that the conversion element mounted to the conductive plate embedded in the first resin cast body faces the lens part provided to the second resin cast body.

By having the portion on which is provided the conversion element and the portion on which is provided the lens part be different resin cast bodies in this manner, the optical communication module can be equipped with not only a conversion element with the photo-receiving part or the photo-emitting part provided at the lower surface, but even a conversion element with the photo-receiving part or the photo-emitting part provided at the upper surface. In addition, the two resin cast bodies are connected via the conductive plate, and thus the two resin cast bodies can be easily fixed by, for example, adhesion or welding with the conductive plate bent.

In addition, in a preferred embodiment, the second resin cast body may be cast from translucent synthetic resin, and the lens part may be cast as a one-piece member with this. Accordingly, the number of components of the optical communication module can be reduced, and manufacturing of the optical communication module can be made easy.

In addition, in a preferred embodiment, the first resin cast body may be formed having a bottom part and a peripheral wall surrounding this, and the portion of the conductive plate may be embedded such that a part or a whole of a surface is exposed at the bottom part. Accordingly, a recess is provided to the first resin cast body that is surrounded by the bottom part and the peripheral wall, and the conversion element can be housed in this recess. In addition, the second resin cast body is fixed extending to an entire periphery of an end part of the peripheral wall. Accordingly, the recess housing the conversion element is sealed.

In addition, in a preferred embodiment, the first resin cast body may be cast from translucent synthetic resin, and also the conductive plate and the conversion element mounted to it may be embedded in the first resin cast body. Accordingly, the conversion element can be easily sealed, and the conversion element can communicate optical signals through the translucent synthetic resin.

In addition, in a preferred embodiment, a cylindrical part may be cast as a one-piece member with the second resin cast body, and an optical communication line such as an optical fiber may be fitted and connected in this cylindrical part. The conversion element is arranged to communicate optical signals, through the lens part provided to the second resin cast body, with the optical communication line that is fitted in the cylindrical part. Accordingly, the positioning of the optical communication line relative to the optical communication module can be made easy, and also the number of components of the optical communication module can be reduced.

In a preferred embodiment, the first resin cast body and the second resin cast body may be connected via the conductive plate. The conversion element is mounted to the portion of the conductive plate embedded within the first resin cast body, and the first resin cast body and the second resin cast body may be fixed and positioned with the conductive plate bent such that the lens part provided to the second resin cast body faces the photoelectric conversion element. With this structure, the optical communication module can be attained equipped with a conversion element having a photo-receiving part or a photo-emitting part at the upper surface, and also the components can be few and the manufacturing can be easy.

### BRIEF DESCRIPTION OF THE DRAWINGS

FIG. 1 is a schematic cross-sectional view showing the structure of an optical communication module according to a preferred embodiment.

FIG. 2 is a schematic cross-sectional view showing the structure of an optical communication module according to a preferred embodiment.

FIG. 3A is a plan view showing the structure of a photoelectric conversion element.

FIG. 3B is a plan view showing the structure of a photoelectric conversion element.

FIG. 4 is a schematic plan view showing the structure of a conductive plate of an optical communication module.

FIG. 5 is a schematic cross-sectional view showing the structure of an optical communication module according to Modified Example 1.

FIG. 6 is a schematic cross-sectional view showing the structure of an optical communication module according to Modified Example 2.

FIG. 7 is a schematic cross-sectional view showing the structure of an existing optical communication module.

### DETAILED DESCRIPTION OF EMBODIMENTS

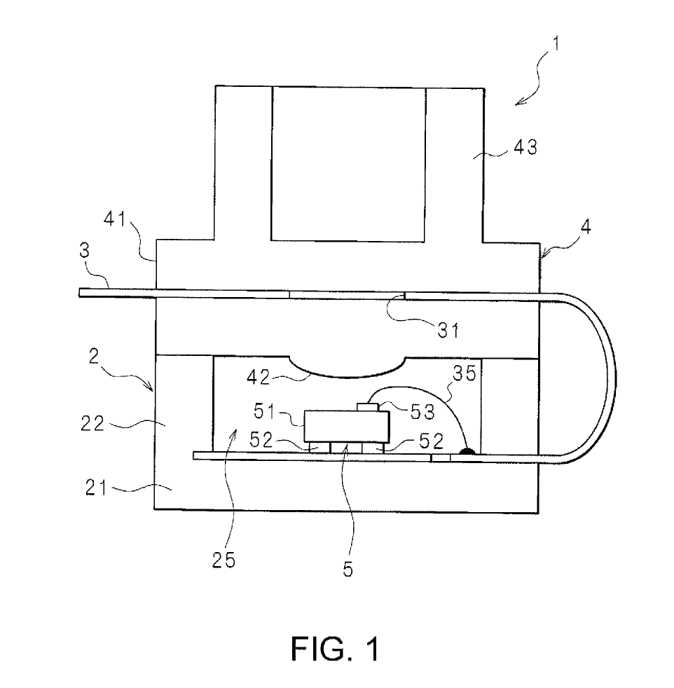

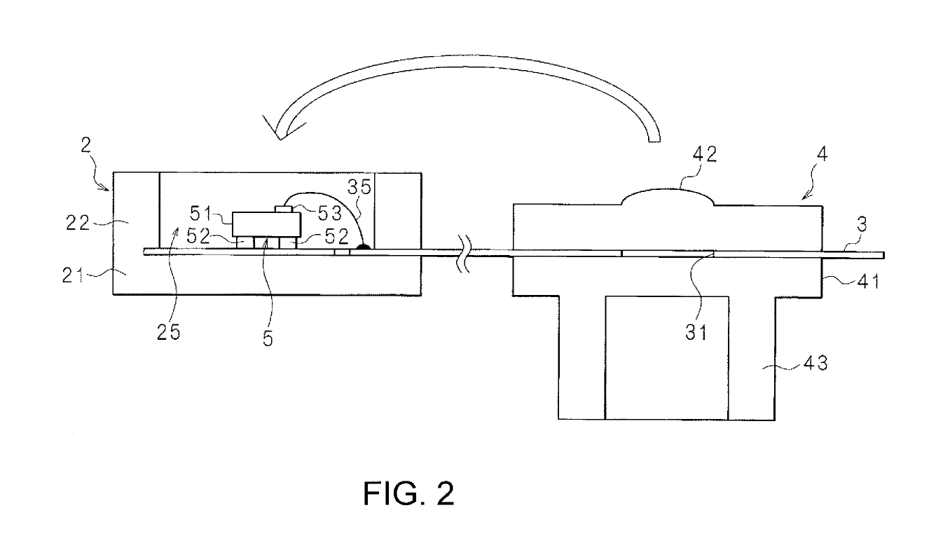

In the following, preferred embodiments are described in detail using the drawings. FIGS. 1 and 2 are schematic cross-sectional views showing the structure of an optical communication module according to a preferred embodiment. In the drawings, 1 is an optical communication module packaging a photoelectric conversion element 5 such as a photodiode or a laser diode. The optical communication module 1 is a component with an optical communication line such as an optical fiber (omitted from the drawings) connected thereto, and arranged to transmit and receive optical signals to and from another optical communication device via this optical communication line and to convert between an optical signal and an electrical signal.

The optical communication module 1 is structured such that the photoelectric conversion element 5 is housed in a translucent housing body 2 and is sealed by a cover body 4. The housing body 2 has a bottom part 21 having a plan view substantially forming a square and a peripheral wall 22 provided at the periphery of the surface of one side (the upper surface in FIG. 1) of this bottom part 21. A recess 25 may be formed by the bottom part 21 and the peripheral wall 22 to house the photoelectric conversion element 5 and the like. The housing body 2 may be formed of, for example, translucent synthetic resin, with the bottom part 21 and the peripheral wall 22 being formed, for example, as a one-piece member, and a plurality of metallic conductive plates 3 may be embedded therein when forming the one-piece member. The conductive plates 3 may be embedded in the bottom part 21 of the housing body 2 such that their upper surfaces are exposed to the inside of the recess 25, and the photoelectric conversion element 5 may be mounted to the exposed portions of the conductive plates 3. The conductive plates 3 are for transmitting and receiving electrical signals between the photoelectric conversion element 5 and the outside. In other words, they correspond to wires that connect to electrical components that form the structural elements of an optical communication circuit which uses the optical communication module 1.

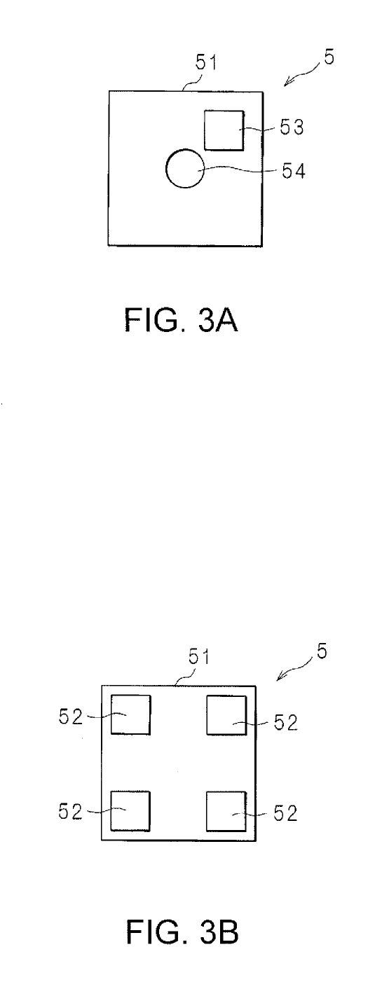

FIGS. 3A and 3B are plan views showing the structure of the photoelectric conversion element 5. In addition, FIG. 3A shows the structure of an upper surface of the photoelectric conversion element 5, and FIG. 3B shows the structure of a lower surface. The photoelectric conversion element 5 has a flat rectangular main body part 51 having a plan view substantially forming a square. At a lower surface of the main body part 51, first terminals 52 are provided at all four corners. The four first terminals 52 are soldered to the conductive plate 3. In addition, substantially at the center of the upper surface of the main body part 51, a photo-emitting part or a photo-receiving part 54 is provided, and also one second terminal 53 is provided. The second terminal 53 is connected to the conductive plate 3 via a wire 35 by wire bonding. The first terminals 52 and the second terminal 53 are terminals for communicating electrical signals from photoelectric conversion, and are, for example, the anode terminal and the cathode terminal of a photodiode or a laser diode.

In addition, the cover body 4 of the optical communication module 1 has a base part 41 having substantially the same substantially square form as the bottom part 21 in a plan view. Substantially at the center of the surface of one side of the base part 41 (this is the surface of the lower side in FIG. 1, the surface of the upper side in FIG. 2, but is called the lower surface below), the lens part 42 is provided. Also, at the surface of the opposite side of the base part 41 (called the upper surface below), a cylinder-shaped cylindrical part 43 protrudes upward to couple the optical communication line. The cover body 4 is formed of, for example, translucent synthetic resin, with the base part 41, the lens part 42, and the cylindrical part 43 being formed as a one-piece member, and a plurality of conductive plates 3 is embedded therein when forming the one-piece member.

The conductive plates 3 embedded in the cover body 4 are the same as the conductive plates 3 embedded in the housing body 2. Specifically, the conductive plates 3 are plate members (a collective member of a plurality of plates) having a length of twice or more the length of one side of the housing body 2 and the cover body 4, with one longitudinal end portion of the conductive plates 3 being embedded inside the housing body 2, and an intermediate portion of the conductive plates 3 being embedded in the cover body 4 separated from the housing body 2 by a prescribed distance. In other words, the housing body 2 and the cover body 4 are connected via the conductive plates 3.

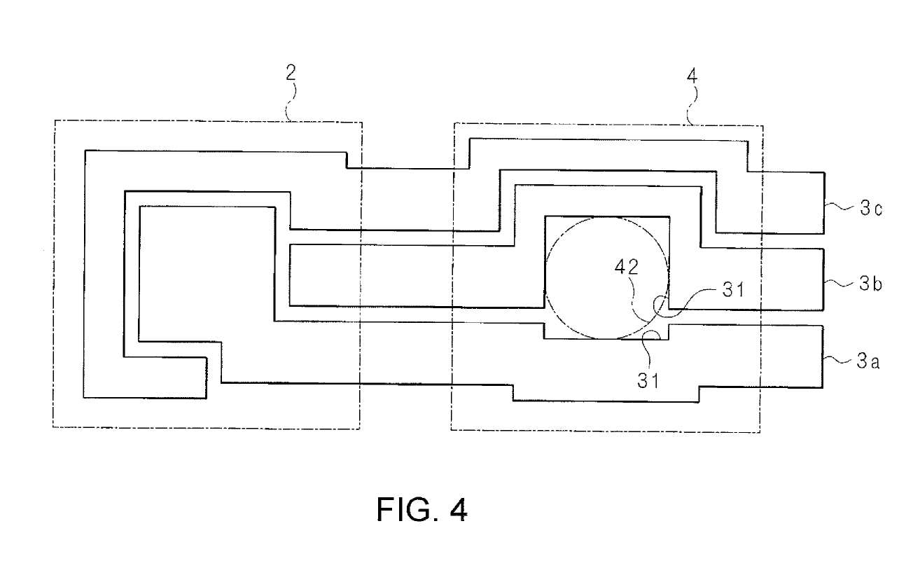

FIG. 4 is a schematic plan view showing the structure of the conductive plates 3 of the optical communication module 1 and shows, with chain lines, the outlines of the housing body 2, the cover body 4, and the lens part 42 superimposed on the shape of the conductive plates 3 as seen from the upper surface. In the depicted example, the optical communication module has three conductive plates 3a-3c. The first conductive plate 3a has a substantially square portion provided at one end and an elongated, substantially oblong portion extending from this portion, the substantially oblong portion being provided, at an intermediate part, with a portion curved in a U-shape. The second conductive plate 3b has an elongated, substantially oblong shape, and is provided, at an intermediate part, with a portion curved in a U-shape. Also, the third conductive plate 3c has at one end a portion curved to surround the substantially square portion of the first conductive plate 3a, and an elongated, substantially oblong portion extending from this portion, the substantially oblong portion being provided, at an intermediate part, with a portion curved in a U-shape.

The substantially square portion of the first conductive plate 3a, a part of the substantially oblong portion extending from this portion, an end portion of the second conductive plate 3b, the curved portion of the one end of third conductive plate 3c, and a part of the substantially oblong portion extending from this portion are embedded in the housing body 2 of the optical communication module 1. Each of the substantially oblong portions of the first to third conductive plates 3a-3c extends from a side surface of the housing body 2 and is exposed to the outside, the first to third conductive plates 3a-3c being positioned substantially parallel between the housing body 2 and the cover body 4.

In addition, the intermediate portions of the elongated, substantially oblong portions of the first to third conductive plates 3a-3c including the portions curved in a U-shape are embedded in the cover body 4 of the optical communication module 1. The portions of the first to third conductive plates 3a-3c curved in a U-shape are circumventing portions 31 circumventing the arrangement position of the lens part 42 so as to not overlie the lens part 42 provided to the cover body 4 (in a plan view). The first to third conductive plates 3a-3c extend from a side surface of the cover body 4 and connect with the housing body 2, and other end portions of the first to third conductive plates 3a-3c also extend, substantially in parallel, from a side surface of the opposite side.

The photoelectric conversion element 5 is mounted to the first conductive plate 3a by the first terminals 52 being soldered to the substantially square portion at the one end. The second terminal 53 provided at the upper surface of the photoelectric conversion element 5 is connected to one end portion of the second conductive plate 3b via the wire 35. The third conductive plate 3c is connected to a ground potential, for example, and is used to shield the optical communication module 1. Also, the portions of the first to third conductive plates 3a-3c extending from the opposite surface of the cover body 4 are used as terminals for connecting the optical communication module 1 to, for example, a circuit board of a communication device.

The conductive plates 3 (the first to third conductive plates 3a-3c) are, for example, thin metallic plates, and are bendable. In the manufacturing process of the optical communication module 1, the housing body 2 and the cover body 4 are cast by positioning one end of each of the unbent conductive plates 3 inside the mold used to cast the housing body 2, positioning the intermediate portions of the conductive plates 3 inside the mold used to cast the cover body 4, pouring translucent material such as a synthetic resin into each mold, and hardening it. In this state, as shown in FIG. 2, the housing body 2 and the cover body 4 are separated by a prescribed distance and are connected via the conductive plates 3.

Next, the conductive plates 3 between the housing body 2 and the cover body 4 are bent, and, with the upper end surface of the peripheral wall 22 of the housing body 2 and the lower surface of the cover body 4 being connected such that the photoelectric conversion element 5 mounted to the inside of the recess 25 of the housing body 2 and the lens part 42 provided to the cover body 4 are facing each other, the housing body 2 and the cover body 4 are fixed by, for example, adhesion or welding. At this time, the housing body 2 and the cover body 4 are positioned such that the center of the photo-emitting part or the photo-receiving part 54 of the photoelectric conversion element 5 and the center of the lens part 42 substantially coincide.

After that, the optical communication module 1 is fixed connected to a circuit board or the like of an optical communication device, with the end portions of the conductive plates 3 extending from the side surface of the cover body 4 being used as connection terminals. Also, an optical communication line of an optical fiber or the like is inserted and fitted in the cylindrical part 43 protruding in the cover body 4 of the optical communication module 1. Accordingly, with the optical communication module 1, the photoelectric conversion element 5 housed in the housing body 2 can communicate optical signals with the optical communication line that is fitted in the cylindrical part 43 through the lens part 42, and also can communicate electrical signals from and to the communication circuit formed by the circuit board or the like of the optical communication device via the conductive plates 3.

With the optical communication module 1 having the above structure, the housing body 2 is resin cast with a portion of the bendable conductive plates 3 embedded therein, the cover body 4 is resin cast with another portion of the conductive plates 3 embedded therein at a prescribed distance from the housing body 2, and also the photoelectric conversion element 5 is mounted to the conductive plates 3 inside the housing body 2. The lens part 42 is provided to the cover body 4, the conductive plates 3 between the housing body 2 and the cover body 4 are bent, and the housing body 2 and the cover body 4 are positioned and fixed such that the photo-emitting part or the photo-receiving part 54 of the photoelectric conversion element 5 faces the lens part 42. In this manner, by making the housing body 2 having the photoelectric conversion element 5 and the cover body 4 having the lens part 42 as separate resin cast bodies, it is possible to attain an optical communication module 1 which uses the photoelectric conversion element 5 having the photo-emitting part or the photo-receiving part 54 provided at its upper surface (the surface opposite from the surface at which the first terminals 52 which connect to the conductive plates 3 are provided). Also, with this structure, the housing body 2 and the cover body 4, which are two resin cast bodies, are connected via the conductive plates 3, and thus the manufacturing of the optical communication module is easily carried out by bending the conductive plates 3 and fixing the two resin cast bodies by adhesion or welding.

In addition, by casting the cover body 4 from translucent synthetic resin and structuring it as a one-piece member with the lens part 42, a reduction in the number of components of the optical communication module 1 and an ease of manufacturing of the optical communication module 1 are possible. Also, by having a structure in which the cylindrical part 43 is formed as a one-piece member with the cover body 4 and the optical communication line is fitted in the cylindrical part 43 and connected, the optical communication line can be easily positioned relative to the optical communication module 1, and also the number of components of the optical communication module 1 can be reduced.

In addition, by housing the photoelectric conversion element 5 in the recess 25 surrounded by the bottom part 21 and the peripheral wall 22 of the housing body 2, mounting the photoelectric conversion element 5 to the conductive plates 3 exposed at the bottom part 21, and fixing the cover body 4 extending to an entire periphery of the upper end surface of the peripheral wall 22, the photoelectric conversion element 5 can be easily and reliably sealed.

An exemplary embodiment of the present invention has been described above. It should be noted that the above exemplary embodiment is merely an example and the present invention is not limited to the detailed embodiment. For example, the configurations and structures and so on of the housing body 2, the conductive plates 3, the cover body 4, and the photoelectric conversion element 5 in the form of this embodiment shown diagrammatically are one example and are not limited to this. Also, in the optical communication module 1, the housing body 2 is a structure cast from translucent material such as a synthetic resin, but it is not limited to this and can also be cast from non-translucent synthetic resin. Also, the cylindrical part 43 is formed with the cover body 4 as a one-piece member, but it is not limited to this and the cylindrical part 43 can be formed as a separate member and fixed to the cover body 4 by adhesion or welding, or the optical communication module 1 can be formed without the cylindrical part 43. Also, in the optical communication module 1, the conductive plates 3 are formed as three conductive plates 3a-3c, but it is not limited to this and can also have two or less, or four or more, conductive plates. Also, the number and position and so on of the first terminals 52 of the photoelectric conversion element 5 are not limited to what is shown in FIG. 3B. The photoelectric conversion element 5 is formed having one second terminal 53, but it is not limited to this and can also have two or more second terminals. Also, the position of the second terminal 53 is not limited to what is shown in FIG. 3A.

### MODIFIED EXAMPLE 1

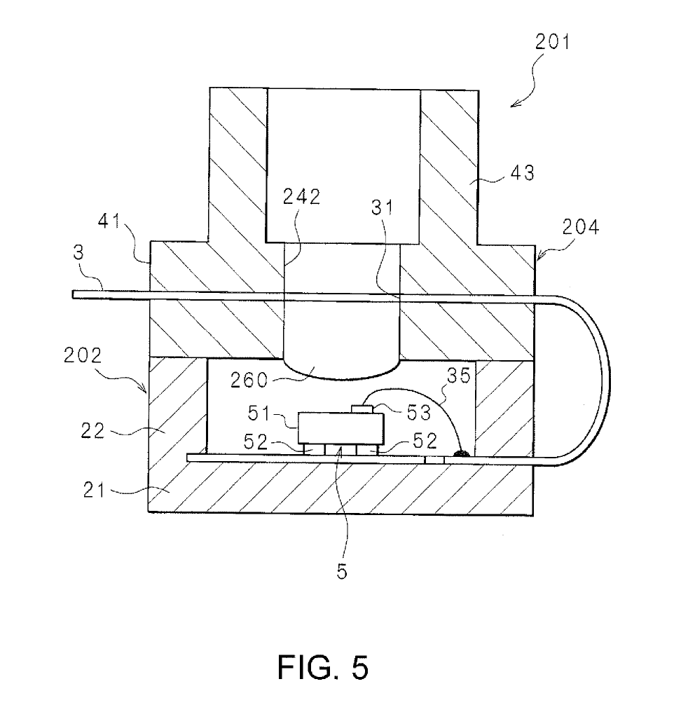

FIG. 5 is a schematic cross-sectional view showing the structure of an optical communication module 201 according to Modified Example 1. In the optical communication module 201 according to Modified Example 1, a housing body 202 and a cover body 204 are cast from non-translucent synthetic resin. Thus, the lens part 260 is formed as a separate member from the cover body 204, and the lens part 260 is attached to the cover body 204 in the manufacturing process of the optical communication module 201.

The lens part 260 is formed of, for example, synthetic resin or glass or the like, and has a substantially cylindrical shape, with a lens surface being formed at one end surface or both end surfaces. Substantially at the center of the base part 41 of the cover body 204 in a plan view, a substantially circular through-hole 242 is formed, and the cylindrical part 43 protrudes at the upper surface of the base part 41 so as to surround this through-hole 242. The lens part 260 is inserted through the through-hole 242 of the base part 41 and is fixed by adhesion or welding or the like.

In this manner, the lens part 260 of the optical communication module 201 can be a separate member from the cover body 204, and the cover body 204 can be cast from non-translucent synthetic resin.

### MODIFIED EXAMPLE 2

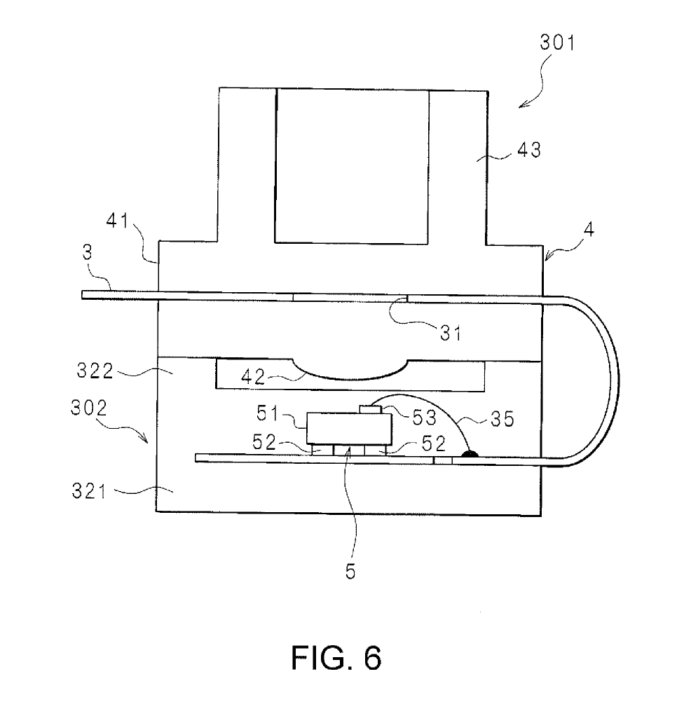

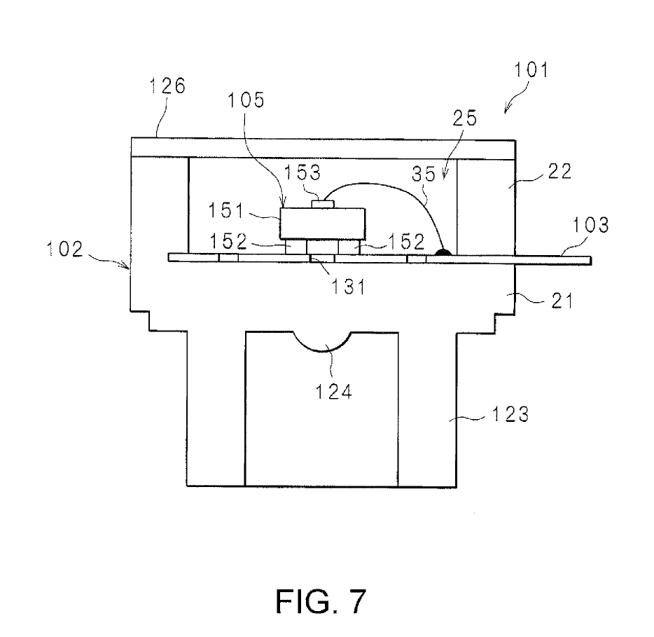

FIG. 6 is a schematic cross-sectional view showing the structure of an optical communication module 301 according to Modified Example 2. In the optical communication module 301 according to Modified Example 2, the structure of the cover body 4 is the same as that shown in FIG. 1, but the structure of the housing body 302 differs from the housing body 2 shown in FIG. 1. In the housing body 302 of the optical communication module 301 according to Modified Example 2, an end part of the conductive plates 3 and the photoelectric conversion element 5 mounted thereto are embedded (resin sealed) inside a base part 321 having a flat, rectangular shape substantially forming a square in a plan view. Also, a peripheral wall 322 is provided at the upper surface of the base part 321, and the cover body 4 is fixed to the upper end surface of the peripheral wall 322 by adhesion or welding or the like.

In the manufacturing process of the optical communication module 301 according to Modified Example 2, after mounting the photoelectric conversion element 5 to the conductive plates 3, the conductive plates 3 and the photoelectric conversion element 5 are housed inside the mold, and the resin casting of the housing body 302 and the cover body 4 is carried out. After that, the conductive plates 3 between the housing body 302 and the cover body 4 are bent, and, with the upper end surface of the peripheral wall 322 of the housing body 302 and the lower surface of the cover body 4 being connected such that the photoelectric conversion element 5 inside the housing body 302 and the lens part 42 provided to the cover body 4 are facing each other, the housing body 202 and the cover body 4 are fixed by, for example, adhesion or welding or the like. The photoelectric conversion element 5 can communicate optical signals with the optical communication line that is fitted in the cylindrical part 43 through the translucent base part 321 and the lens part 42.

In this manner, the photoelectric conversion element 5 of the optical communication module 301 can be sealed when resin casting the housing body 302.

1. An optical communication module comprising:
a conversion element configured to convert an optical signal to an electrical signal or an electrical signal to an optical signal;
a bendable conductive plate on which the conversion element is mounted;
a first resin cast body cast with a first portion of the conductive plate embedded therein;
a second resin cast body cast with a second portion of the conductive plate embedded therein; and
a lens part provided on the second resin cast body,
the conversion element being mounted to the first portion of the conductive plate embedded in the first resin cast body,
the first resin cast body and the second resin cast body being fixed with the conductive plate bent such that the conversion element faces the lens part.

2. The optical communication module of claim 1, wherein
the second resin cast body is cast from translucent synthetic resin, and
the lens part is cast as a one-piece member with the second resin cast body.

3. The optical communication module of claim 1, wherein
the first resin cast body has a bottom part and a peripheral wall surrounding the bottom part,
the first portion of the conductive plate is embedded in the first resin cast body such that a part or a whole of a first surface of the conductive plate is exposed to the bottom part, and
the second resin cast body is fixed extending to an entire periphery of an end part of the peripheral wall.

4. The optical communication module of claim 1, wherein
the first resin cast body is cast from translucent synthetic resin, and
the conversion element is embedded in the first resin cast body.

5. The optical communication module of claim 1, further comprising
a cylindrical part cast as a one-piece member with the second resin cast body and in which an optical communication line is fitted,
the conversion element being arranged to communicate through the lens part an optical signal with the optical communication line that is fitted in the cylindrical part.

6. The optical communication module of claim 3, further comprising
a cylindrical part cast as a one-piece member with the second resin cast body and in which an optical communication line is fitted,
the conversion element being arranged to communicate through the lens part an optical signal with the optical communication line that is fitted in the cylindrical part,

7. The optical communication module of claim 1, wherein
the conversion element has at least one first terminal disposed on a first side of the conversion element and a photo-receiving part or a photo-emitting part disposed on a second, opposite side of the conversion element.

8. The optical communication module of claim 7, wherein
the at least one terminal connects with the conductive plate on the first side of the conversion element.

9. The optical communication module of claim 7, wherein
the second, opposite side of the conversion element faces the lens part such that the photo-receiving part or the photo-emitting part is disposed facing the lens part.

10. The optical communication module of claim 7, wherein
the at least one terminal connects with the conductive plate on the first side of the conversion element, and
the second, opposite side of the conversion element faces the lens part such that the photo-receiving part or the photo-emitting part is disposed facing the lens part.

11. The optical communication module of claim 1, wherein
the conductive plate has a third portion that is disposed between the first and second portions of the conductive plate such that the first portion is separated from the second portion by a prescribed distance defined by a length of the third portion.

12. The optical communication module of claim 3, wherein
the bottom part and the peripheral wall of the first resin cast body form a recess, and the conversion element is housed in the recess.

13. The optical communication module of claim 12, wherein
the conductive plate has a second surface that is exposed to the recess, with the conversion element being mounted to the second surface.

14. The optical communication module of claim 2, wherein
the first resin cast body has a bottom part and a peripheral wall surrounding the bottom part,
the first portion of the conductive plate is embedded in the first resin cast body such that a part or a whole of a first surface of the conductive plate is exposed to the bottom part, and
the second resin cast body is fixed extending to an entire periphery of an end part of the peripheral wall.

15. The optical communication module of claim 2, wherein
the first resin cast body is cast from translucent synthetic resin, and
the conversion element is embedded in the first resin cast body.
